(19) United States
(12) Patent Application Publication
(10) Pub. No.: US 2025/0048850 A1
(43) Pub. Date: Feb. 6, 2025

(54) DISPLAY PANEL AND DISPLAY DEVICE

(71) Applicant: Wuhan Tianma Microelectronics Co., Ltd., Wuhan (CN)

(72) Inventors: Qiyong KE, Wuhan (CN); Xianchi WANG, Wuhan (CN); Chunmei GAO, Wuhan (CN)

(73) Assignee: Wuhan Tianma Microelectronics Co., Ltd., Wuhan (CN)

(21) Appl. No.: 18/925,876

(22) Filed: Oct. 24, 2024

(30) Foreign Application Priority Data
Apr. 24, 2024 (CN) 202410502003.9

(51) Int. Cl. H10K 59/122; H10K 59/124; H10K 59/80

(52) U.S. Cl. CPC H10K 59/122; H10K 59/124; H10K 59/80515

(57) ABSTRACT

A display panel includes a planarization layer, an anode on a side of the planarization layer, and a pixel defining layer on a side of the anode facing away from the planarization layer; where the pixel defining layer is provided with a pixel opening, and part of the anode is exposed through the pixel opening; the planarization layer is provided with a groove, the groove surrounds the pixel opening, and the groove penetrates through at least part of the planarization layer; and the anode covers the groove, and an end of the anode is located at a side of the groove facing away from the pixel opening. The groove is disposed in the planarization layer, the anode is adjusted to cover the groove, and the end of the anode extends to the side of the groove facing away from the pixel opening.

### CROSS-REFERENCE TO RELATED APPLICATION(S)

This application claims priority to Chinese Patent Application No. 202410502003.9 filed Apr. 24, 2024, the disclosure of which is incorporated herein by reference in its entirety.

### TECHNICAL FIELD

Embodiments of the present disclosure relate to the field of display technology and, in particular, to a display panel and a display device.

### BACKGROUND

With the continuous development of display technology, display panels have been widely applied in production and life. To better meet requirements, it is an important task to ensure the structural stability of a display panel to ensure the better visual experience of the display panel.

### SUMMARY

Embodiments of the present disclosure provide a display panel and a display device, where a groove is disposed in a planarization layer, an anode is adjusted to cover the groove, and an end of the anode extends to a side of the groove facing away from a pixel opening.

In a first aspect, the embodiments of the present disclosure provide a display panel including a planarization layer, an anode on a side of the planarization layer, and a pixel defining layer on a side of the anode facing away from the planarization layer.

The pixel defining layer is provided with a pixel opening, and part of the anode is exposed through the pixel opening.

The planarization layer is provided with a groove, the groove surrounds the pixel opening, and the groove penetrates through at least part of the planarization layer; and the anode covers the groove, and an end of the anode is located at a side of the groove facing away from the pixel opening.

In a second aspect, the embodiments of the present disclosure provide a display device including the display panel described in the first aspect.

The embodiments of the present disclosure provide the display panel. The display panel includes the planarization layer, the anode, and the pixel defining layer; where the anode is disposed on one side of the planarization layer, the pixel defining layer is disposed on the side of the anode facing away from the planarization layer, the pixel opening is disposed in the pixel defining layer, part of the anode is exposed through the pixel opening, and a light-emitting film is disposed in the pixel opening, thereby implementing the display function of the display panel; and the groove in the planarization layer penetrates through at least part of the planarization layer and is arranged around the pixel opening. The anode covers the groove at the position of the groove.

### BRIEF DESCRIPTION OF DRAWINGS

To illustrate technical solutions in example embodiments of the present disclosure more clearly, the drawings used in the description of the embodiments are briefly described below.

FIG. 1 is a first structure diagram of a display panel according to embodiments of the present disclosure.

FIG. 2 is a first enlarged view of region A in FIG. 1.

FIG. 3 is a first sectional view of FIG. 2 taken along a line B-B′.

FIG. 4 is a second sectional view of FIG. 2 taken along a line B-B′.

FIG. 5 is a third sectional view of FIG. 2 taken along a line B-B′.

FIG. 6 is a fourth sectional view of FIG. 2 taken along a line B-B′.

FIG. 7 is a fifth sectional view of FIG. 2 taken along a line B-B′.

FIG. 8 is a sixth sectional view of FIG. 2 taken along a line B-B′.

FIG. 9 is a sectional view of FIG. 1 taken along a line C-C′.

FIG. 10 is a sectional view of FIG. 1 taken along a line D-D′.

FIG. 11 is a second structure diagram of a display panel according to embodiments of the present disclosure.

FIG. 12 is a sectional view of FIG. 11 taken along a line E-E′.

FIG. 13 is a sectional view of FIG. 11 taken along a line F-F′.

FIG. 14 is a sectional view of FIG. 11 taken along a line G-G′.

FIG. 15 is a second enlarged view of region A in FIG. 1.

FIG. 16 is a first sectional view of FIG. 15 taken along a line H-H′.

FIG. 17 is a second sectional view of FIG. 15 taken along a line H-H′.

FIG. 18 is a third sectional view of FIG. 15 taken along a line H-H′.

FIG. 19 is a sectional view of FIG. 11 taken along a line I-I′.

FIG. 20 is a third enlarged view of region A in FIG. 1.

FIG. 21 is a fourth enlarged view of region A in FIG. 1.

FIG. 22 is a fifth enlarged view of region A in FIG. 1.

FIG. 23 is an enlarged view of region M in FIG. 1.

FIG. 24 is a structure diagram of a display device according to embodiments of the present disclosure.

### DETAILED DESCRIPTION

The present disclosure is further described in detail below in conjunction with the drawings and embodiments. It is to be understood that the embodiments described herein are intended to illustrate the present disclosure and not to limit the present disclosure. Additionally, it is to be noted that for ease of description, only part, not all, of structures related to the present disclosure are illustrated in the drawings.

It is to be noted that terms such as “first” and “second” in the description, claims, and above drawings of the present disclosure are used for distinguishing between similar objects and are not necessarily used for describing a particular order or sequence. It is to be understood that data used in this manner are interchangeable where appropriate so that the embodiments of the present disclosure described herein can be implemented in an order not illustrated or described herein. Additionally, terms “including”, “having”, and any variations thereof are intended to encompass a non-exclusive inclusion. For example, a system, product, or device that includes a series of units not only includes the expressly listed steps or units but may also include other units that are not expressly listed or are inherent to the product or device.

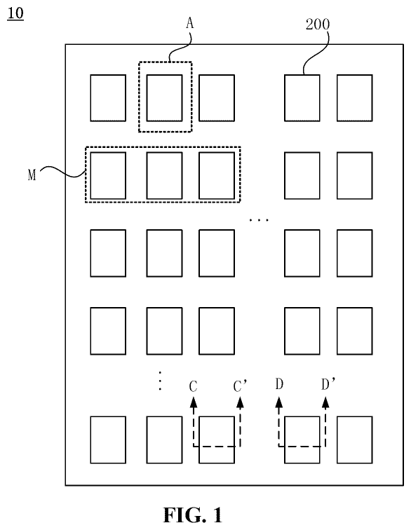

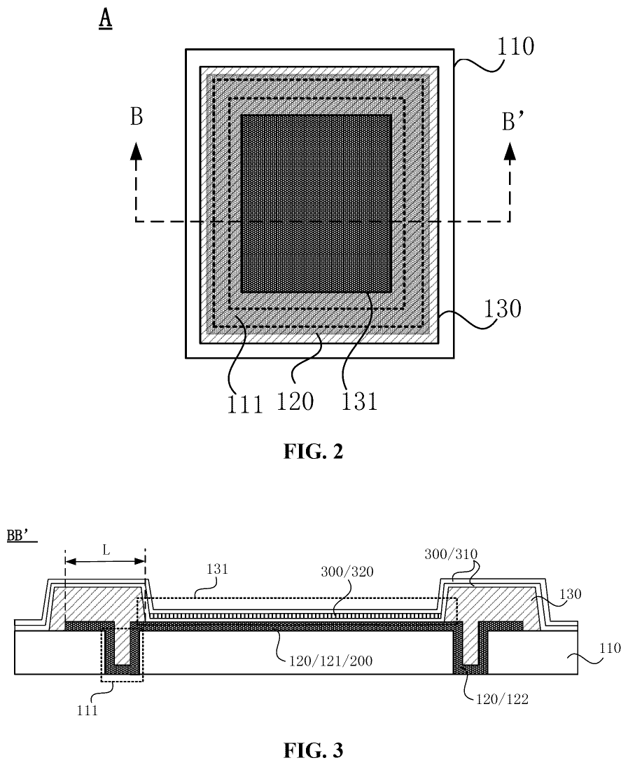

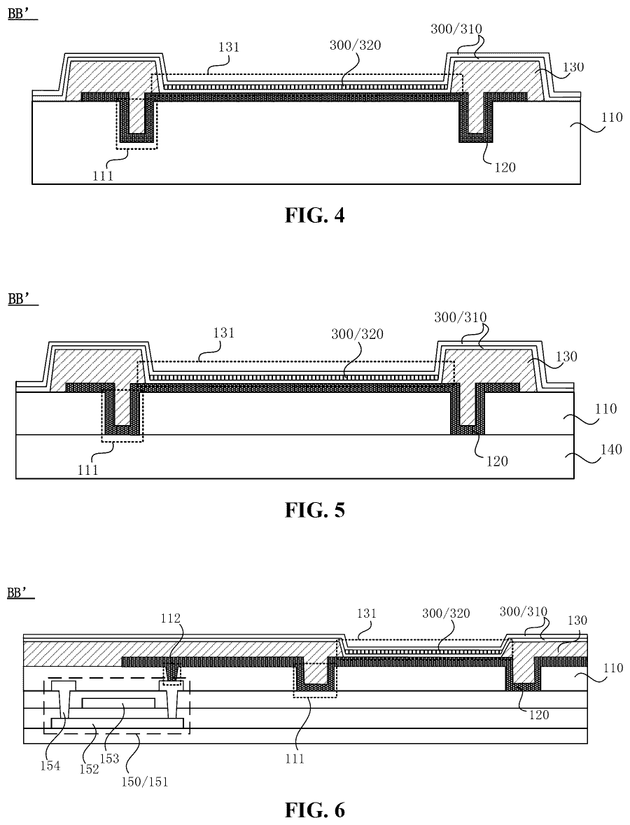

FIG. 1 is a first structure diagram of a display panel according to embodiments of the present disclosure. FIG. 2 is a first enlarged view of region A in FIG. 1. FIG. 3 is a first sectional view of FIG. 2 taken along a line B-B′. FIG. 4 is a second sectional view of FIG. 2 taken along a line B-B′. Referring to FIGS. 1 to 4, embodiments of the present disclosure provide a display panel 10, and the display panel 10 includes a planarization layer 110, an anode 120 on a side of the planarization layer 110, and a pixel defining layer 130 on a side of the anode 120 facing away from the planarization layer 110; where the pixel defining layer 130 is provided with a pixel opening 131, and part of the anode 120 is exposed through the pixel opening 131; the planarization layer 110 is provided with a groove 111, the groove 111 surrounds the pixel opening 131, and the groove 111 penetrates through at least part of the planarization layer 110; and the anode 120 covers the groove 111, and an end of the anode 120 is located at a side of the groove 111 facing away from the pixel opening 131.

Specifically, referring to FIGS. 1 to 3, the display panel 10 includes the planarization layer 110, the anode 120, and the pixel defining layer 130, the anode 120 is disposed on one side of the planarization layer 110, the pixel defining layer 130 is disposed on the side of the anode 120 facing away from the planarization layer 110, a lighting-emitting film 300 is also disposed on the side of the anode 120 facing away from the planarization layer 110, and the lighting-emitting film 300 includes common films 310 and a light-emitting layer 320. The common films 310 include a hole injection layer, a hole transport layer, an electron transport layer, and an electron injection layer. Specific films are not shown one by one. Specific film structures may be adaptively adjusted according to different display panels 10, which are not shown one by one in the embodiments of the present disclosure.

Referring to FIGS. 2 to 4, the pixel defining layer 130 is provided with the pixel opening 131, and part of the anode 120 at the position of the pixel opening 131 is not covered by the pixel defining layer 130, which may be understood as that the pixel defining layer 130 covers part of the anode 120 and does not cover the anode 120 at the position of the pixel opening 131. The display panel 10 performs light emission and display at the position of the pixel opening 131 to achieve the display effect of the display panel 10.

Water vapor is generated in a film preparation process of the display panel 10, or some gases are released by aged films. A material of the planarization layer 110 adsorbs water. Therefore, the water vapor or the gases are transmitted to the pixel opening 131 and affect the structural stability of the display panel 10. For example, the water vapor or other gases are transmitted to the lighting-emitting film 300 over the anode 120, so the lighting-emitting film 300 shrinks, affecting the display effect of the display panel 10. In the display panel 10 provided by the embodiments of the present disclosure, the planarization layer 110 and the anode 120 are adjusted so that interference of the water vapor or the gases with a film of the display panel 10 is reduced or eliminated, thereby ensuring the overall display effect of the display panel 10.

Specifically, the planarization layer 110 is provided with the groove 111. Referring to FIGS. 2 to 4, the groove 111 is arranged around the pixel opening 131, and the groove 111 penetrates through at least part of the planarization layer 110. For example, referring to FIG. 3, the groove 111 penetrates through the entire planarization layer 110. Referring to FIG. 4, the groove 111 penetrates through part of the planarization layer 110. A penetration depth of the groove 111 may be adaptively adjusted according to different requirements.

Further, referring to FIGS. 2 to 4, in the display panel 10, the anode 120 covers the groove 111, and the end of the anode 120 is located at the side of the groove 111 facing away from the pixel opening 131. From the top view, referring to FIG. 2, the anode 120 is in an exposed state at the position of the pixel opening 131, the end of the anode 120 extends to the side of the groove 111 facing away from the pixel opening 131, and the anode 120 completely covers the groove 111. From a sectional view, referring to FIGS. 3 and 4, the anode 120 from the pixel opening 131 to the end of the anode 120 entirely covers the groove 111 and extends to an outer end of the groove 111 facing away from the pixel opening 131. It may be understood as that the entire anode 120 extends over a relatively long length until the anode 120 extends to the side of the groove 111 facing away from the pixel opening 131 and covers the groove 111.

Specifically, referring to FIGS. 3 and 4, the groove 111 is disposed in the planarization layer 110 and the anode 120 covers the groove 111 so that the groove 111 and the anode 120 in the groove 111 can block water vapor or gases possible to exist in the planarization layer 110 corresponding to the pixel opening 131, ensuring that the water vapor or the gases in the planarization layer 110 corresponding to the pixel opening 131 are not easily transmitted to the pixel opening 131 along a thickness direction of the display panel 10. Thus, the interference of the water vapor or the gases with the light-emitting film 300 on the side of the anode 120 facing away from the planarization layer 110 can be avoided, and the stability of a film structure at the position of the pixel opening 131 can be ensured, thereby ensuring the structural stability of the display panel 10 and the display effect of the display panel 10.

Further, referring to FIGS. 2 to 4, the end of the anode 120 extends to the side of the groove facing away from the pixel opening, and the relatively long anode 120 increases a transmission path of the water vapor or the gases in the planarization layer 110 and hinders the water vapor or the gases possible to exist in the planarization layer 110 from being transmitted to the pixel defining layer 130. Thus, the interference of the water vapor or the gases with some films on the side of the anode 120 facing away from the planarization layer 110 can also be avoided.

To sum up, the groove 111 is disposed, the anode 120 covers the groove 111, and the overall extension length of the anode 120 is increased so that the structural stability of the display panel 10 can be ensured, the stability of the lighting-emitting film 300 in the display panel 10 can be prevented from being affected by the water vapor or the gases, and the overall display effect of the display panel 10 can be ensured.

To conclude, according to the display panel provided by the embodiments of the present disclosure, the groove is disposed in the planarization layer and the anode covers the groove at the position of the groove in the display panel. The groove and the anode in the groove can effectively hinder the outward transmission of the water vapor or other gases in the planarization layer at the position of the pixel opening, thereby avoiding the interference of the water vapor or the gases with the lighting-emitting film on the side of the anode facing away from the planarization layer. Further, the end of the anode extends to the side of the groove facing away from the pixel opening. Such an arrangement manner of the anode increases the transmission path of the water vapor or the gases in the planarization layer so that the interference of the water vapor or the gases with some films on the side of the anode facing away from the planarization layer can also be avoided, thereby ensuring the structural stability of the display panel and the display effect of the display panel.

FIG. 5 is a third sectional view of FIG. 2 taken along a line B-B′. Referring to FIGS. 2 and 5, the display panel 10 further includes an inorganic insulating layer 140 on a side of the planarization layer 110 facing away from the anode 120; where the groove 111 penetrates through the planarization layer 110, and the anode 120 covering the groove 111 is in contact with the inorganic insulating layer 140.

Specifically, referring to FIG. 5, the display panel 10 further includes the inorganic insulating layer 140, and the inorganic insulating layer 140 is disposed on the side of the planarization layer 110 facing away from the anode 120. The groove 111 may penetrate through the entire planarization layer 110; therefore, the anode 120 covering the groove 111 is in direct contact with an adjacent film of the planarization layer 110 facing away from the anode 120, that is, in contact with the inorganic insulating layer 140.

Specifically, referring to FIG. 5, the anode 120 is in contact with the inorganic insulating layer 140 at the position of the groove 111, which is equivalent to that the groove 111 completely disconnects a part of planarization layer 110 surrounded by the groove 111 from a part of planarization layer 110 outside the groove 111. Through the groove 111, the anode 120 in the groove 111, and the inorganic insulating layer 140, the planarization layer 110 corresponding to the pixel opening 131 along the thickness direction of the display panel 10 is equivalent to a fully surrounded structure. Along the thickness direction of the display panel 10, the water vapor or the gases possible to exist in the planarization layer 110 corresponding to the pixel opening 131 have no release path and cannot be transmitted outward. Therefore, the groove 111 completely penetrates through the planarization layer 110 so that the outward transmission of the water vapor or the gases in the planarization layer 110 can be hindered fundamentally, thereby effectively preventing the interference of the water vapor or the gases with the lighting-emitting film 300 in the display panel 10 and ensuring the display effect of the display panel 10.

Still referring to FIGS. 2 and 4, the groove 111 penetrates through part of the planarization layer 110.

Specifically, a pixel circuit is further disposed on the side of the planarization layer 110 facing away from the anode 120, and the pixel circuit is electrically connected to the anode 120 to provide a display signal for the anode 120, thereby ensuring the display function of the display panel 10. To ensure the electrical connection between the pixel circuit and the anode 120, a signal wire exists in the display panel 10.

Further, referring to FIG. 4, the groove 111 may penetrate through only part of the planarization layer 110, that is, the groove 111 does not penetrate through the entire planarization layer 110. Therefore, the anode 120 at the position of the groove 111 is not in direct contact with a film on the side of the planarization layer 110 facing away from the anode 120 so that the anode 120 at the position of the groove 111 is prevented from the interference of the signal wire and the film on the side of the planarization layer 110 facing away from the anode 120, thereby ensuring the stability of signal transmission. Meanwhile, the groove 111 is arranged with greater freedom. The depth of the groove 111 may be adjusted according to different requirements of different display panels 10, that is, the groove 111 has high universality.

FIG. 6 is a fourth sectional view of FIG. 2 taken along a line B-B′. Referring to FIGS. 2 and 6, the display panel 10 further includes a pixel circuit 150 on the side of the planarization layer 110 facing away from the anode 120; the planarization layer 110 is further provided with an anode connection via 112, and the anode 120 is electrically connected to the pixel circuit 150 through the anode connection via 112; and the groove 111 is disposed on a side of the anode connection via 112 facing the pixel opening 131.

Specifically, referring to FIG. 6, the display panel 10 further includes the pixel circuit 150, and the pixel circuit 150 is disposed on the side of the planarization layer 110 facing away from the anode 120. The pixel circuit 150 is electrically connected to the anode 120 to provide the display signal for the anode 120, thereby ensuring the display function of the display panel 10. For example, the pixel circuit 150 includes multiple transistors 151, and each transistor 151 includes an active layer 152, a gate 153, and a source and drain 154. A specific circuit structure of the pixel circuit 150, the number of films of the pixel circuit 150, and a type of the pixel circuit 150 are not described in detail in the embodiments of the present disclosure.

Referring to FIG. 6, the planarization layer 110 further includes the anode connection via 112, the anode 120 extends to the anode connection via 112, and the electrical connection between the anode 120 and the pixel circuit 150 is ensured through the anode connection via 112. Further, the groove 111 is disposed on the side of the anode connection via 112 facing the pixel opening 131, that is, the planarization layer 110 includes both the groove 111 and the anode connection via 112, and the groove 111 and the anode connection via 112 are disposed independently. The groove 111 is arranged with great freedom and may be closer to the pixel opening 131 to better block the water vapor and the gases in the planarization layer 110 below the pixel opening 131 and better protect the lighting-emitting film 300 disposed in the pixel opening 131. Moreover, the anode connection via 112 generally has a relatively large distance from an anode body portion. The anode body portion here may be understood as an anode portion exposed through the pixel opening 131. The groove 111 is disposed on the side of the anode connection via 112 facing the pixel opening 131, which is better in accordance with an actual structure and technique, and the groove 111 does not affect the arrangement manners or positions of other structures and effectively hinders the transmission of the water vapor or the gases, thereby ensuring the overall display effect of the display panel 10.

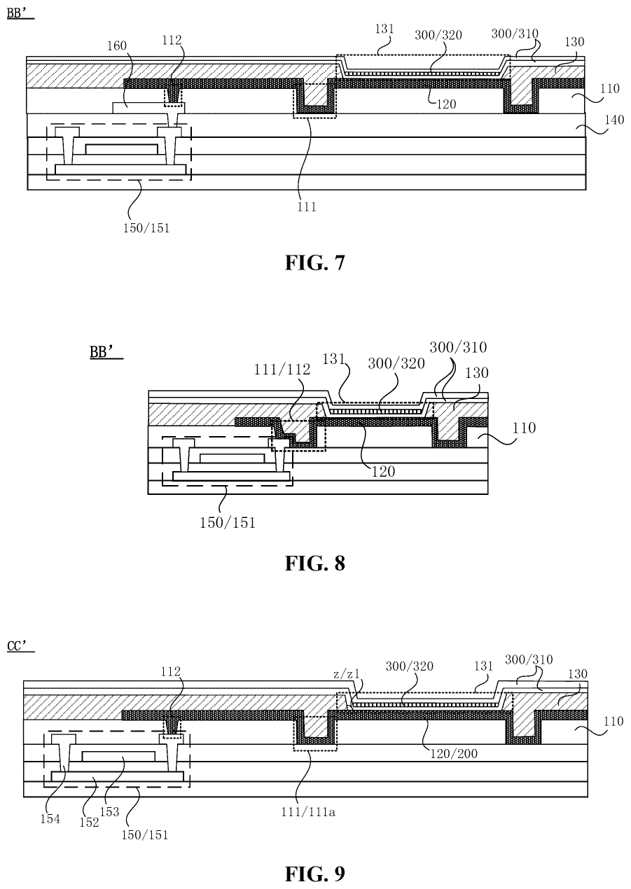

FIG. 7 is a fifth sectional view of FIG. 2 taken along a line B-B′. Referring to FIGS. 2 and 7, the display panel 10 further includes the inorganic insulating layer 140 on the side of the planarization layer 110 facing away from the anode 120 and a signal wire 160 between the inorganic insulating layer 140 and the planarization layer 110; and the anode 120 covering the groove 111 is insulated from the signal wire 160.

Specifically, referring to FIG. 7, in the display panel 10, the inorganic insulating layer 140 is disposed between the planarization layer 110 and films where the pixel circuit 150 is located, and the signal wire 160 is disposed between the inorganic insulating layer 140 and the planarization layer 110. The signal wire 160 may serve as a transmission wire of a signal in the display panel, for example, a transmission wire of a data signal, a transmission wire of a touch signal, a transmission wire of a power signal, or a transmission wire of another signal required for the normal display of the display panel. The normal display function of the display panel and an additional function of the display panel other than display, such as a touch function, are implemented through the signal wire 160. Meanwhile, the signal wire 160 between the inorganic insulating layer 140 and the planarization layer 110 may serve as a connection bridge between the pixel circuit 150 and the anode 120 (as shown in FIG. 7), thereby reducing a punching depth in the display panel 10 and achieving connection stability while reducing a punching difficulty.

Further, referring to FIG. 7, the anode 120 covering the groove 111 is insulated from the signal wire 160, that is, the anode at the position of the groove 111 is not electrically connected to the signal wire for transmitting another signal, and the groove 111 and the anode 120 in the groove 111 are mainly used for display and hindering the transmission of the water vapor or the gases.

The signal wire 160 disposed between the anode 120 and the inorganic insulating layer 140 can effectively ensure the signal transmission to the anode 120 and prevent a signal short-circuit between the anode 120 at the position of the groove 111 and another signal wire. When the hindering of the water vapor and the gases is ensured, the stable transmission of different signals is ensured, that is, not only the structural stability of the display panel 10 but also the signal transmission effect of the display panel 10 are ensured, thereby improving the overall display effect of the display panel 10.

FIG. 8 is a sixth sectional view of FIG. 2 taken along a line B-B′. Referring to FIGS. 8 and 2, the display panel 10 further includes the pixel circuit 150 on the side of the planarization layer 110 facing away from the anode 120; the planarization layer 110 is further provided with the anode connection via 112, and the anode 120 is electrically connected to the pixel circuit 150 through the anode connection via 112; and the groove 111 is integrated with the anode connection via 112.

Specifically, the planarization layer 110 includes the groove 111 and the anode connection via 112, where the groove 111 and the anode 120 in the groove 111 may be used for hindering the transmission of the water vapor or the gases in the planarization layer 110, thereby ensuring the structural stability of the display panel 10. The anode connection via 112 is used for ensuring the electrical connection between the anode 120 and the pixel circuit 150 and ensuring that the anode 120 acquires a corresponding electrical signal, thereby ensuring the display function of the display panel 10.

Further, referring to FIG. 8, the groove 111 is integrated with the anode connection via 112, that is, the anode connection via 112 can not only ensure the electrical connection with the pixel circuit 150 but also collaborate with the anode 120 to hinder the water vapor or the gases in the planarization layer 110. In the integrated design manner, a separate groove 111 can be omitted, a technique preparation cost can be reduced, and an occupied area of a region other than the pixel opening 131 can be reduced, thereby facilitating an increase in the pixel distribution density of the display panel 10 and an improvement of the display resolution of the display panel 10.

FIG. 9 is a sectional view of FIG. 1 taken along a line C-C′. FIG. 10 is a sectional view of FIG. 1 taken along a line D-D′. Referring to FIGS. 1, 9, and 10, the display panel 10 further includes a plurality of sub-pixels 200, where each sub-pixel 200 includes the anode 120; and a light emission angle z of the sub-pixel 200 is positively correlated to a grooving volume of the groove 111 surrounding the sub-pixel 200.

Specifically, referring to FIG. 1, the display panel 10 includes the plurality of sub-pixels 200, and the sub-pixels 200 perform display to ensure that the display panel 10 implements the display function. Further, referring to FIGS. 9 and 10, the light emission angle z of the sub-pixel 200 may be understood as a maximum angle of light emission of the sub-pixel 200 at the position of the pixel opening 131, and the light emission angle z of the sub-pixel is supplementary to an inclination angle of the pixel defining layer 130 at the position of the pixel opening 131. The light emission angle z of the sub-pixel 200 may affect the light emission effect of the sub-pixel 200. Therefore, different sub-pixels 200 may have different light emission angles z through adjustments according to different requirements to adjust the overall display of the display panel 10, thereby ensuring the display effect of the display panel 10.

Further, not only can the water vapor or the gases in the planarization layer 110 be hindered by the groove 111 in the planarization layer 110, but also the light emission angle z of the sub-pixel 200 may be adjusted through the groove 111. The grooving volumes of different grooves 111 are adjusted so that light emission angles z are adjusted. Specifically, the greater the grooving volume of the groove 111, the greater the volume of the pixel defining layer 130 filled in the groove 111. Therefore, the smaller the inclination angle of the pixel defining layer 130 at the position of the pixel opening 131, the larger the corresponding light emission angle z. For example, as shown by the comparison of FIGS. 9 and 10, the grooving volume of the groove 111 in FIG. 9 is smaller than the grooving volume of the groove 111 in FIG. 10, the volume of the pixel defining layer 130 filled in the groove 111 in FIG. 9 is smaller than the volume of the pixel defining layer 130 filled in the groove 111 in FIG. 10, the inclination angle of the pixel defining layer 130 at the position of the pixel opening 131 in FIG. 9 is greater than the inclination angle of the pixel defining layer 130 at the position of the pixel opening 131 in FIG. 10, and the light emission angle z of the sub-pixel 200 in FIG. 9 is smaller than the light emission angle z of the sub-pixel 200 in FIG. 10.

Therefore, in the case where the groove 111 in the planarization layer 110 hinders the water vapor or the gases, ensuring the structural stability of the display panel 10, the volume of the groove 111 may be adjusted so that the light emission angle z is adjusted, thereby adjusting the light emission effect of the display panel 10 and ensuring the overall display effect of the display panel 10.

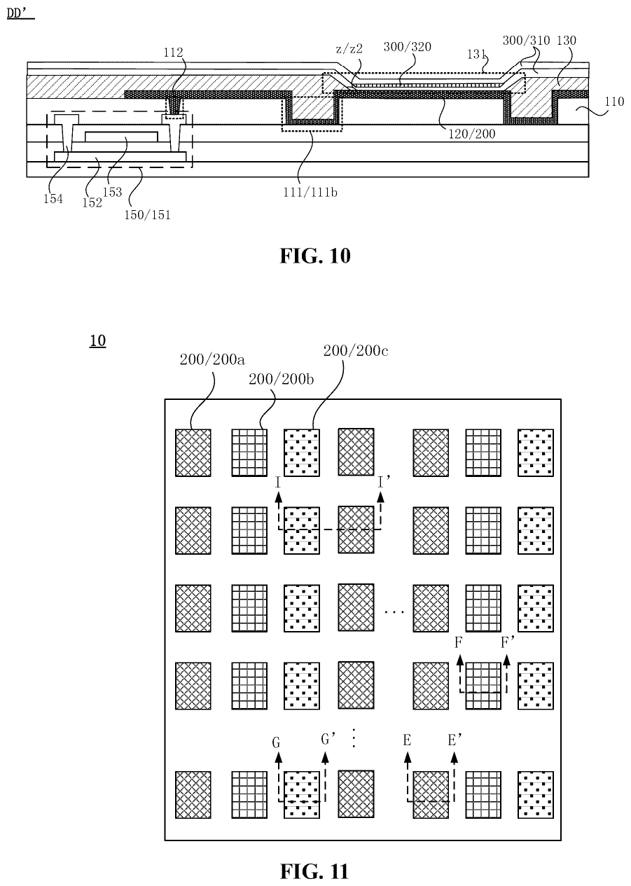

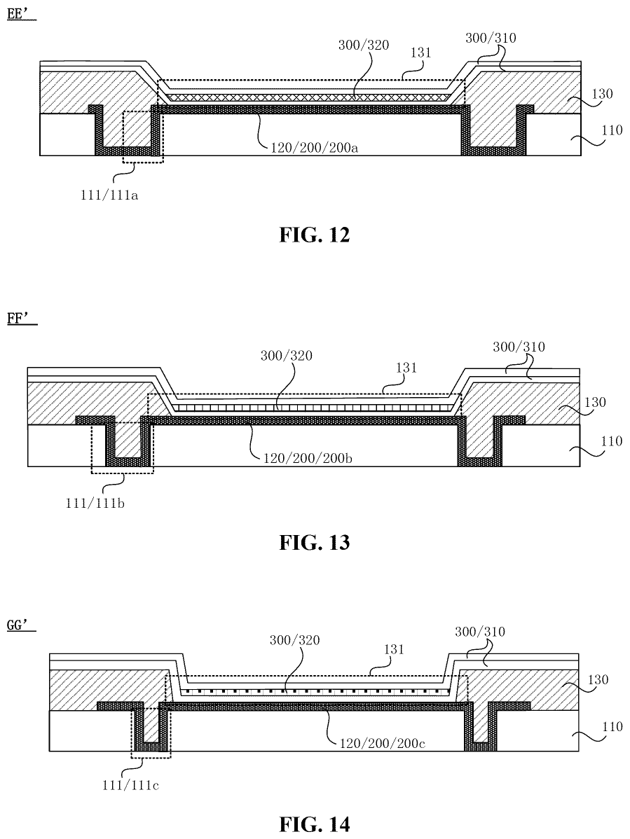

FIG. 11 is a second structure diagram of a display panel according to an embodiment of the present disclosure. FIG. 12 is a sectional view of FIG. 11 taken along a line E-E′. FIG. 13 is a sectional view of FIG. 11 taken along a line F-F′. FIG. 14 is a sectional view of FIG. 11 taken along a line G-G′. Referring to FIGS. 11 to 14, the sub-pixels 200 include a first sub-pixel 200a, a second sub-pixel 200b, and a third sub-pixel 200c, where the first sub-pixel 200a, the second sub-pixel 200b, and the third sub-pixel 200c have different emission colors; a brightness decay of the first sub-pixel 200a varying with a viewing angle is greater than a brightness decay of the second sub-pixel 200b varying with the viewing angle, and the brightness decay of the second sub-pixel 200b varying with the viewing angle is greater than a brightness decay of the third sub-pixel 200c varying with the viewing angle; the groove 111 includes a first groove 111a surrounding the first sub-pixel 200a, a second groove 111b surrounding the second sub-pixel 200b, and a third groove 111c surrounding the third sub-pixel 200c; and a grooving volume of the first groove 111a is greater than a grooving volume of the second groove 111b, and the grooving volume of the second groove 111b is greater than a grooving volume of the third groove 111c.

Specifically, referring to FIG. 11, the display panel 10 includes the plurality of sub-pixels 200, and the sub-pixels 200 include the first sub-pixel 200a, the second sub-pixel 200b, and the third sub-pixel 200c with the different emission colors. The sub-pixels 200 of different colors are arranged in the display panel 10 to ensure the color display effect of the display panel 10.

Further, the brightness decays of the sub-pixels 200 of different colors varying with the viewing angle are different. As described above, the grooving volume of the groove 111 surrounding the sub-pixel 200 is adjusted so that the light emission angle of the sub-pixel 200 can be adjusted. Specifically, since the decays of the sub-pixels 200 of different colors varying with the viewing angle are different, the volumes of the grooves 111 surrounding different sub-pixels 200 are configured to be different so that the light emission decays of different sub-pixels 200 are adjusted, thereby ensuring the display effect of the display panel 10.

The brightness decay of the first sub-pixel 200a varying with the viewing angle is greater than the brightness decay of the second sub-pixel 200b varying with the viewing angle, and the brightness decay of the second sub-pixel 200b varying with the viewing angle is greater than the brightness decay of the third sub-pixel 200c varying with the viewing angle; therefore, the grooving volumes of different grooves 111 are adjusted to ensure the display effect of the display panel 10. Referring to FIGS. 11 to 14, the grooving volume of the first groove 111a is adjusted to be greater than the grooving volume of the second groove 111b, and the grooving volume of the second groove 111b is adjusted to be greater than the grooving volume of the third groove 111c. That is, according to the light emission decays of different sub-pixels 200 at a large viewing angle, the grooving volumes of the grooves surrounding the sub-pixels 200 are adaptively adjusted to adjust light decays, thereby ensuring the better overall display effect of the display panel 10. It is to be noted that to clearly observe differences between the grooving volumes of different grooves 111, the pixel circuit 150 on the side of the planarization layer 110 facing away from the anode 120 is not shown in FIGS. 11 to 14.

It is to be noted that FIG. 11 illustrates only an example of an arrangement manner of the sub-pixels with different emission colors and is not to limit the arrangement manner. The display panel provided by the embodiments of the present disclosure is applicable to various pixel arrangements, for example, pixel arrangements based on pixel borrowing, such as a “diamond” arrangement or a “YYG” arrangement. The specific pixel arrangement manner is not limited in the embodiments of the present disclosure.

Optionally, the first sub-pixel 200a includes a blue sub-pixel, the second sub-pixel 200b includes a red sub-pixel, and the third sub-pixel 200c includes a green sub-pixel.

Specifically, the sub-pixels 200 of different colors may be the blue sub-pixel, the red sub-pixel, and the green sub-pixel, respectively. The brightness decay of the first sub-pixel 200a varying with the viewing angle is greater than the brightness decay of the second sub-pixel 200b varying with the viewing angle, and the brightness decay of the second sub-pixel 200b varying with the viewing angle is greater than the brightness decay of the third sub-pixel 200c varying with the viewing angle. In conjunction with the actual situations of red, green, and blue luminescence, the first sub-pixel 200a may be the blue sub-pixel, the second sub-pixel 200b may be the red sub-pixel, and the third sub-pixel 200c may be the green sub-pixel. Some display panels 10 may further include white sub-pixels, and these display panels 10 are shown one by one by way of example in the embodiments of the present disclosure.

It is to be noted that based on different light-emitting materials, the first sub-pixel, the second sub-pixel, and the third sub-pixel may be other combinations. The preceding embodiments are described as feasible implementation manners. In the embodiments of the present disclosure, an emission color of the first sub-pixel, an emission color of the second sub-pixel, and an emission color of the third sub-pixel are not limited as long as the following is satisfied: the brightness decay of the first sub-pixel varying with the viewing angle is greater than the brightness decay of the second sub-pixel varying with the viewing angle, and the brightness decay of the second sub-pixel varying with the viewing angle is greater than the brightness decay of the third sub-pixel varying with the viewing angle.

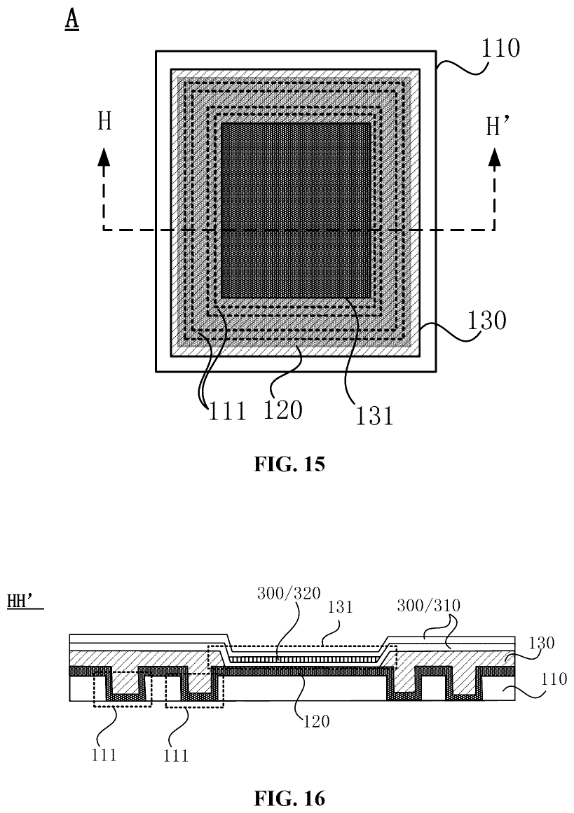

FIG. 15 is a second enlarged view of region A in FIG. 1. FIG. 16 is a first sectional view of FIG. 15 taken along a line H-H′. Referring to FIGS. 15 and 16, the planarization layer 110 is provided with a plurality of grooves 111, and the plurality of grooves 111 each surrounds the pixel opening 131.

The number of grooves 111 surrounding the pixel opening 131 in the planarization layer 110 may be diverse. Referring to FIGS. 15 and 16, two grooves 111 are disposed around the pixel opening 131 in the planarization layer 110, for example. It is to be noted that to clearly observe a difference in the number of grooves 111, the pixel circuit 150 on the side of the planarization layer 110 facing away from the anode 120 is not shown in FIGS. 15 and 16.

Specifically, referring to FIGS. 15 and 16, the plurality of grooves 111 surrounding the pixel opening 131 are disposed in the planarization layer 110 so that the transmission path of the water vapor or the gases released by aged film structures in the planarization layer 110 can be further extended, thereby ensuring that the light-emitting film 300 at the position of the pixel opening 131 is not affected by the water vapor or the gases, ensuring the structural stability of the film, and ensuring the display effect of the display panel 10.

Further, the plurality of grooves 111 are filled with the pixel defining layer 130, that is, the pixel defining layer 130 covers the plurality of grooves 111. Along the thickness direction of the display panel 10, the flatness of the pixel defining layer 130 overlapping the groove 111 is different from the flatness of the pixel defining layer 130 not overlapping the groove 111. It may be understood as that the pixel defining layer 130 generates non-flatness due to the design of the groove 111 and therefore, a film (for example, the light-emitting film 300) prepared subsequently on the pixel defining layer 130 increases in length since the film is bonded to the pixel defining layer 130, that is, the length of the light-emitting film 300 is increased. It is equivalent to lengthening a transmission path of a leakage current between two adjacent sub-pixels 200 due to the grooves 111 so that undesired light emission between two adjacent sub-pixels 200 is reduced, thereby ensuring the display effect of the display panel 10. Referring to FIGS. 15 and 16, the number of the grooves 111 is increased so that the transmission path of the leakage current between two adjacent sub-pixels 200 can be further lengthened, and the undesired light emission between two adjacent sub-pixels 200 can be further reduced, better ensuring a display contrast between different sub-pixels of the display panel 10.

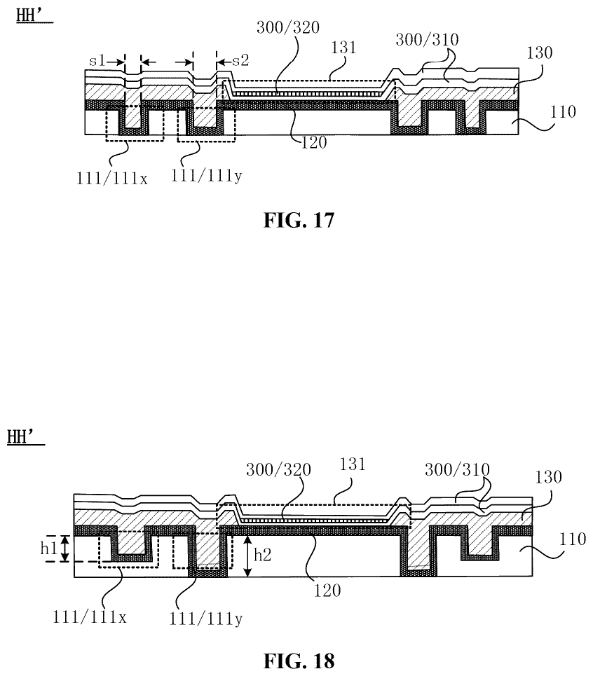

FIG. 17 is a second sectional view of FIG. 15 taken along a line H-H′. Referring to FIGS. 15 and 17, two grooves 111 among the plurality of grooves 111 have different grooving volumes.

Specifically, in the case where the plurality of grooves 111 surrounding the pixel opening 131 are disposed in the planarization layer 110, the grooving volumes of different grooves 111 may be different and therefore, different amounts of the pixel defining layer 130 are filled in the different grooves 111 so that the pixel defining layer 130 at the positions of different grooves 111 has a more significant flatness difference, the extension length of the lighting-emitting film 300 between two adjacent sub-pixels 200 is further increased, the transmission path of the leakage current between two adjacent sub-pixels 200 is further lengthened, and the undesired light emission between two adjacent sub-pixels 200 is further reduced, better ensuring the display effect of the display panel 10.

For example, referring to FIG. 17, an example in which two grooves 111 are disposed in the planarization layer 110 is shown, and the grooving volumes of different grooves 111 are different. In FIG. 17, an example in which a grooving volume of a groove 111x is smaller than a grooving volume of a groove 111y is shown. An amount of the pixel defining layer 130 filled in the groove 111y is greater than an amount of the pixel defining layer 130 filled in the groove 111x. Therefore, the flatness of the pixel defining layer 130 at the position of the groove 111y is different from the flatness of the pixel defining layer 130 at the position of the groove 111x. It can be known that the grooves 111 with different grooving volumes can further increase the non-flatness of a surface of the pixel defining layer 130, further increase the extension length of the lighting-emitting film 300 between two adjacent sub-pixels 200, and further reduce the undesired light emission between two adjacent sub-pixels 200, thereby ensuring the overall display effect of the display panel 10.

FIG. 18 is a third sectional view of FIG. 15 taken along a line H-H′. Referring to FIGS. 15, 17, and 18, the two grooves 111 with the different grooving volumes have different grooving depths and/or different grooving areas.

Specifically, referring to FIGS. 17 and 18, an example in which the planarization layer 110 includes two grooves 111 surrounding the pixel opening 131 is shown. The specific number of grooves 111 may be adaptively adjusted according to actual requirements, which is not specifically limited in the embodiments of the present disclosure.

Further, when the planarization layer 110 includes the plurality of grooves 111, a difference between the grooving volumes of different grooves 111 is adjusted so that the non-flatness of the surface of the pixel defining layer 130 can be further increased, the extension length of the lighting-emitting film 300 between two adjacent sub-pixels 200 can be further increased, and the undesired light emission between two adjacent sub-pixels 200 can be further reduced, thereby ensuring the overall display effect of the display panel 10.

To adjust the specific difference between the grooving volumes of the grooves 111, the grooving depths and/or the grooving areas of the grooves 111 may be adjusted. For example, referring to FIG. 17, a grooving area of the groove 111x is s1, a grooving area of the groove 111y is s2, and s1<s2 so that it can be ensured that the grooving volume of the groove 111x is smaller than the grooving volume of the groove 111y. Referring to FIG. 18, a grooving depth of the groove 111x is h1, a grooving depth of the groove 111y is h2, and h1<h2 so that it can be ensured that the grooving volume of the groove 111x is smaller than the grooving volume of the groove 111y. Further, for different grooves 111 in the planarization layer 110, both the grooving areas and the grooving depths may be adjusted. To conclude, the difference between the grooving volumes of the grooves 111 is implemented in various manners.

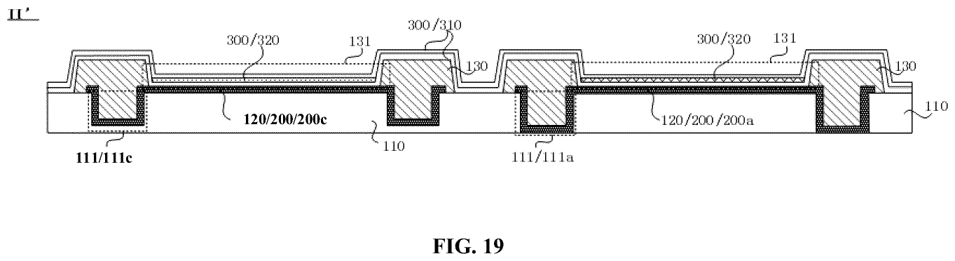

FIG. 19 is a sectional view of FIG. 11 taken along a line I-I′. Referring to FIGS. 11 and 19, the display panel 10 further includes the plurality of sub-pixels 200, where each sub-pixel 200 includes the anode 120; and the sub-pixels 200 include the blue sub-pixel and the green sub-pixel, and two grooves 111 with different grooving volumes exist between the blue sub-pixel and the green sub-pixel.

Specifically, referring to FIG. 11, the display panel 10 includes the plurality of sub-pixels 200, for example, the red sub-pixel, the blue sub-pixel, and the green sub-pixel, where a leakage current between the blue sub-pixel and the green sub-pixel is relatively large. The existence of the two grooves 111 with different grooving volumes between the blue sub-pixel and the green sub-pixel is considered so that undesired light emission between the blue sub-pixel and the green sub-pixel adjacent to each other is reduced, thereby ensuring the overall display effect of the display panel 10. Further, grooves 111 with different grooving volumes may be disposed between any two of the red sub-pixel, the blue sub-pixel, and the green sub-pixel, further ensuring the overall display effect of the display panel 10.

For example, referring to FIG. 19, an example in which the sub-pixel 200a is the blue sub-pixel and the sub-pixel 200c is the green sub-pixel is shown, and a grooving depth of the groove 111a corresponding to the blue sub-pixel 200a is adjusted to be greater than a grooving depth of the groove 111c corresponding to the green sub-pixel 200c to ensure that the two grooves 111 with different grooving volumes exist between the blue sub-pixel 200a and the green sub-pixel 200c. It is to be noted that a difference between the grooving volumes of the grooves 111 corresponding to the sub-pixels 200 of different colors is embodied by the grooving depth of the groove 111 in FIG. 19, and the number of grooves 111 and the grooving area of the groove 111 may also be considered. It can be known that the volumes of the grooves 111 between sub-pixels 200 that are prone to the leakage current are adjusted in various manners.

Further, multiple embodiments of a shape of the groove 111 are described below.

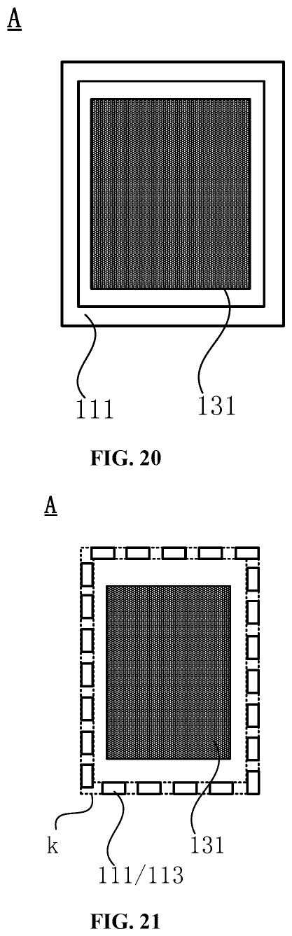

FIG. 20 is a third enlarged view of region A in FIG. 1. Referring to FIG. 20, the groove 111 includes a continuous closed groove.

Specifically, referring to FIG. 20, the groove 111 surrounding the pixel opening 131 is the continuous closed groove. The groove 111 configured to be a closed structure can better hinder the transmission path of the water vapor or the gases in the planarization layer 110, better ensuring the structural stability of the display panel 10. Moreover, the continuous closed groove is prepared by a relatively simple technique, so the technique preparation cost of the continuous closed groove in the display panel 10 is relatively low.

FIG. 21 is a fourth enlarged view of region A in FIG. 1. Referring to FIG. 21, the groove 111 includes a plurality of sub-grooves 113 disposed independently, and a contour of a connecting line between the plurality of sub-grooves 113 surrounds the pixel opening 131.

Specifically, referring to FIG. 21, the groove 111 includes the plurality of sub-grooves 113 disposed independently, and the contour along which the plurality of sub-grooves 113 are arranged surrounds the pixel opening 131. For the contour, refer to a dashed line k in FIG. 21.

Further, the plurality of sub-grooves 113 are arranged around the pixel opening 131 so that the plurality of sub-grooves 113 can hinder the transmission path of the water vapor or the gases in the planarization layer 110, thereby ensuring the structural stability of the display panel 10. Further, the plurality of sub-grooves 113 are arranged and the pixel defining layer 130 needs to be filled in the plurality of sub-grooves 113 so that the non-flatness of the pixel defining layer 130 is further increased, the extension length of the lighting-emitting film 300 between two adjacent sub-pixels is further increased, the transmission path of the leakage current between two adjacent sub-pixels is further lengthened, and the undesired light emission between two adjacent sub-pixels is further reduced, better ensuring the display effect of the display panel 10.

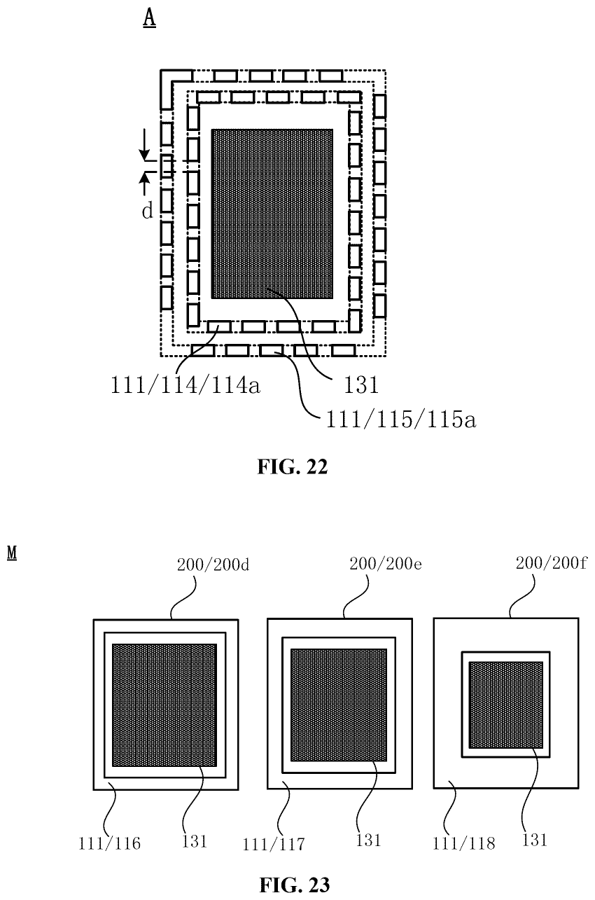

FIG. 22 is a fifth enlarged view of region A in FIG. 1. Referring to FIG. 22, the planarization layer 110 is provided with the plurality of grooves 111; the plurality of grooves 111 include a fourth groove 114 and a fifth groove 115 arranged in sequence along a direction in which the pixel opening 131 points to the plurality of grooves 111; the fourth groove 114 includes a plurality of first sub-grooves 114a disposed independently, and a gap d exists between two adjacent first sub-grooves 114a; the fifth groove 115 includes a plurality of second sub-grooves 115a disposed independently; and along the direction in which the pixel opening 131 points to the plurality of grooves 111, each second sub-groove 115a overlaps the gap d.

Specifically, multiple grooves 111 may surround the pixel opening 131. In FIG. 22, two grooves 111 are shown as an example, where the two grooves 111 are the fourth groove 114 and the fifth groove 115 along the direction in which the pixel opening 131 points to the grooves 111. Further, the fourth groove 114 and the fifth groove 115 each include multiple sub-grooves disposed independently, the fourth groove 114 includes the plurality of first sub-grooves 114a disposed independently, and the fifth groove 115 includes the plurality of second sub-grooves 115a disposed independently. Although the fourth groove 114 and the fifth groove 115 each include multiple sub-grooves, a contour of the plurality of first sub-grooves 114a surrounds the pixel opening 131, and a contour of the plurality of second sub-grooves 115a surrounds the pixel opening 131, thereby ensuring a hindering effect of the grooves 111 on the water vapor or the gases in the planarization layer 110 and ensuring the overall display effect of the display panel 10. Moreover, the plurality of first sub-grooves 114a and the plurality of second sub-grooves 115a further increase the non-flatness of the pixel defining layer 130 and further lengthen the transmission path of the leakage current between two adjacent sub-pixels, better ensuring the display effect of the display panel 10.

Further, referring to FIG. 22, the gap d exists between two adjacent first sub-grooves 114a, and the second sub-groove 115a overlaps the gap d along the direction in which the pixel opening 131 points to the grooves 111, which may be understood as that the outer second sub-groove 115a shields the gap d between inner first sub-grooves 114a. The fourth groove 114 and the fifth groove 115 collaborate in a staggered manner to surround the entire pixel opening 131 in a closed manner, further ensuring the hindering effect on the water vapor or the gases in the planarization layer 110. When the non-flatness of the pixel defining layer 130 is increased, the transmission of the water vapor or the gases can be hindered, better ensuring the structural stability of the display panel 10.

FIG. 23 is an enlarged view of region M in FIG. 1. Referring to FIGS. 1 to 3 and 23, the display panel 10 further includes the plurality of sub-pixels 200, where each sub-pixel 200 includes the anode 120; the sub-pixels 200 include a fourth sub-pixel 200d, a fifth sub-pixel 200e, and a sixth sub-pixel 200f, where the fourth sub-pixel 200d, the fifth sub-pixel 200e, and the sixth sub-pixel 200f have different emission colors; a pixel opening 131 of the fourth sub-pixel 200d is greater than a pixel opening 131 of the fifth sub-pixel 200e, and the pixel opening 131 of the fifth sub-pixel 200e is greater than a pixel opening 131 of the sixth sub-pixel 200f; the groove 111 includes a sixth groove 116 surrounding the fourth sub-pixel 200d, a seventh groove 117 surrounding the fifth sub-pixel 200e, and an eighth groove 118 surrounding the sixth sub-pixel 200f; and a grooving area of the sixth groove 116 is less than a grooving area of the seventh groove 117, and the grooving area of the seventh groove 117 is less than a grooving area of the eighth groove 118.

The display panel 10 includes the plurality of sub-pixels 200 of different colors to ensure the color display effect of the display panel 10. However, the pixel openings 131 corresponding to the sub-pixels 200 of different colors are different in size. Therefore, the grooves 111 surrounding the pixel openings 131 of different sub-pixels 200 have different spaces. For the flexibility with which the groove 111 is disposed, such as the number, the grooving volume, and the grooving shape, different spaces are to be reserved for the grooves 111 in conjunction with different sub-pixels 200 to implement different settings, thereby reducing the preparation difficulty of the groove 111 and reducing the preparation cost of the display panel 10 when ensuring the display effect of the display panel 10.

Specifically, referring to FIG. 23, the fourth sub-pixel 200d, the fifth sub-pixel 200e, and the sixth sub-pixel 200f of different colors are shown as an example, the pixel opening 131 of the fourth sub-pixel 200d is greater than the pixel opening 131 of the fifth sub-pixel 200e, and the pixel opening 131 of the fifth sub-pixel 200e is greater than the pixel opening 131 of the sixth sub-pixel 200f. On the premise that the pixel openings 131 are different, a preparation space reserved for the sixth groove 116 is less than a preparation space reserved for the seventh groove 117, and the preparation space reserved for the seventh groove 117 is less than a preparation space reserved for the eighth groove 118. Therefore, the grooving area of the sixth groove 116 is less than the grooving area of the seventh groove 117, and the grooving area of the seventh groove 117 is less than the grooving area of the eighth groove 118. It is to be noted that in FIG. 23, one groove 111 surrounding each pixel opening 131 is shown as an example, and a difference between the grooves 111 surrounding different pixel openings 131 may also be embodied by the number of grooves 111 or the grooving depth of the groove 111, which are not shown one by one here.

To sum up, in the display panel 10, the grooving areas of the grooves 111 surrounding different sub-pixels 200 may be determined according to the pixel openings 131 of the sub-pixels 200, thereby reducing the grooving difficulty.

Still referring to FIGS. 1 to 3, the anode 120 includes a first anode portion 121 and a second anode portion 122 connected to each other, the first anode portion 121 is exposed through the pixel opening 131, and the pixel defining layer 130 covers the second anode portion 122; and along a direction in which the first anode portion 121 points to the second anode portion 122, the length L of the second anode portion 122 satisfies that L≥1 mm.

Specifically, referring to FIG. 3, the anode 120 includes the first anode portion 121 and the second anode portion 122, the first anode portion 121 is exposed at the position of the pixel opening 131, and the second anode portion 122 is shielded by the pixel defining layer 130. Along the direction in which the first anode portion 121 points to the second anode portion 122, the length of the second anode portion 122 is greater than 1 mm, for example, 2 mm, 3 mm, or 5 mm, and the length of the second anode portion 122 may be adaptively adjusted according to an actual situation. The length of the second anode portion 122 is limited so that the overall extension length of the anode 120 can be ensured, and the relatively long anode 120 increases the transmission path of the water vapor or the gases in the planarization layer 110 and hinders the water vapor or the gases possible to exist in the planarization layer 110 from being transmitted to the pixel defining layer 130. The interference of the water vapor or the gases with some films on the side of the anode 120 facing away from the planarization layer 110 can also be avoided, thereby ensuring the overall display effect of the display panel 10.

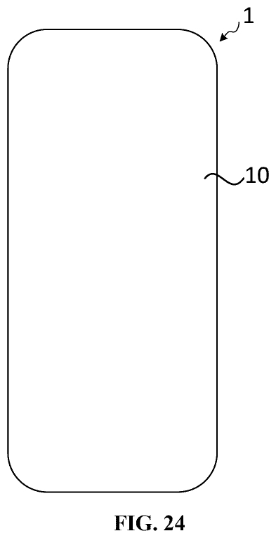

Based on the same inventive concept, the embodiments of the present disclosure further provide a display device. FIG. 24 is a structure diagram of a display device according to an embodiment of the present disclosure. As shown in FIG. 24, a display device 1 includes the display panel 10 according to any one of the preceding embodiments. Therefore, the display device 1 provided in the embodiments of the present disclosure has the corresponding beneficial effects in the preceding embodiments. The details are not repeated here. For example, the display device 1 may be an electronic device such as a mobile phone, a computer, a smart wearable device (for example, a smart watch), and an in-vehicle display device, which is not limited in the embodiments of the present disclosure.

It is to be noted that the preceding are preferred embodiments of the present disclosure and technical principles used therein. It is to be understood by those skilled in the art that the present disclosure is not limited to the embodiments described herein and those skilled in the art can make various apparent modifications, adaptations, and substitutions without departing from the scope of the present disclosure. Therefore, although the present disclosure has been described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A display panel, comprising a planarization layer, an anode on a side of the planarization layer, and a pixel defining layer on a side of the anode facing away from the planarization layer; wherein
the pixel defining layer is provided with a pixel opening, and part of the anode is exposed through the pixel opening; and
the planarization layer is provided with a groove, the groove surrounds the pixel opening, and the groove penetrates through at least part of the planarization layer; and the anode covers the groove, and an end of the anode is located at a side of the groove facing away from the pixel opening.

2. The display panel of claim 1, further comprising an inorganic insulating layer on a side of the planarization layer facing away from the anode;
wherein the groove penetrates through the planarization layer, and the anode covering the groove is in contact with the inorganic insulating layer.

3. The display panel of claim 1, wherein the groove penetrates through part of the planarization layer.

4. The display panel of claim 1, further comprising a pixel circuit on a side of the planarization layer facing away from the anode;
wherein the planarization layer is further provided with an anode connection via, and the anode is electrically connected to the pixel circuit through the anode connection via; and
the groove is disposed on a side of the anode connection via facing the pixel opening.

5. The display panel of claim 4, further comprising an inorganic insulating layer on the side of the planarization layer facing away from the anode and a signal wire between the inorganic insulating layer and the planarization layer;
wherein the anode covering the groove is insulated from the signal wire.

6. The display panel of claim 1, further comprising a pixel circuit on a side of the planarization layer facing away from the anode;
wherein the planarization layer is further provided with an anode connection via, and the anode is electrically connected to the pixel circuit through the anode connection via; and
the groove is integrated with the anode connection via.

7. The display panel of claim 1, further comprises a plurality of sub-pixels, wherein a sub-pixel of the plurality of sub-pixels comprises the anode; and
a light emission angle of the sub-pixel is positively correlated to a grooving volume of the groove surrounding the sub-pixel.

8. The display panel of claim 7, wherein the plurality of sub-pixels comprise a first sub-pixel, a second sub-pixel, and a third sub-pixel, wherein the first sub-pixel, the second sub-pixel, and the third sub-pixel have different emission colors;
a brightness decay of the first sub-pixel varying with a viewing angle is greater than a brightness decay of the second sub-pixel varying with the viewing angle, and the brightness decay of the second sub-pixel varying with the viewing angle is greater than a brightness decay of the third sub-pixel varying with the viewing angle;
the groove comprises a first groove surrounding the first sub-pixel, a second groove surrounding the second sub-pixel, and a third groove surrounding the third sub-pixel; and
a grooving volume of the first groove is greater than a grooving volume of the second groove, and the grooving volume of the second groove is greater than a grooving volume of the third groove.

9. The display panel of claim 8, wherein the first sub-pixel comprises a blue sub-pixel, the second sub-pixel comprises a red sub-pixel, and the third sub-pixel comprises a green sub-pixel.

10. The display panel of claim 1, wherein the planarization layer is provided with a plurality of grooves, and the plurality of grooves each surround the pixel opening.

11. The display panel of claim 10, wherein two grooves among the plurality of grooves have different grooving volumes.

12. The display panel of claim 11, wherein the two grooves with the different grooving volumes have different grooving depths and/or different grooving areas.

13. The display panel of claim 11, further comprises a plurality of sub-pixels, wherein a sub-pixel of the plurality of sub-pixels comprises the anode; and
the plurality of sub-pixels comprise a blue sub-pixel and a green sub-pixel, and two grooves with different grooving volumes exist between the blue sub-pixel and the green sub-pixel.

14. The display panel of claim 1, wherein the groove comprises a continuous closed groove.

15. The display panel of claim 1, wherein the groove comprises a plurality of sub-grooves disposed independently, and a contour of a connecting line between the plurality of sub-grooves surrounds the pixel opening.

16. The display panel of claim 15, wherein the planarization layer is provided with a plurality of grooves;
the plurality of grooves comprise a fourth groove and a fifth groove arranged in sequence along a direction in which the pixel opening points to the plurality of grooves;
the fourth groove comprises a plurality of first sub-grooves disposed independently, and a gap exists between two adjacent first sub-grooves;
the fifth groove comprises a plurality of second sub-grooves disposed independently; and
along the direction in which the pixel opening points to the plurality of grooves, a second sub-groove of the plurality of second sub-grooves overlaps the gap.

17. The display panel of claim 1, further comprises a plurality of sub-pixels, wherein a sub-pixel of the plurality of sub-pixels comprises the anode;
the plurality of sub-pixels comprise a fourth sub-pixel, a fifth sub-pixel, and a sixth sub-pixel, wherein the fourth sub-pixel, the fifth sub-pixel, and the sixth sub-pixel have different emission colors;
a pixel opening of the fourth sub-pixel is greater than a pixel opening of the fifth sub-pixel, and the pixel opening of the fifth sub-pixel is greater than a pixel opening of the sixth sub-pixel;
the groove comprises a sixth groove surrounding the fourth sub-pixel, a seventh groove surrounding the fifth sub-pixel, and an eighth groove surrounding the sixth sub-pixel; and
a grooving area of the sixth groove is less than a grooving area of the seventh groove, and the grooving area of the seventh groove is less than a grooving area of the eighth groove.

18. The display panel of claim 1, wherein the anode comprises a first anode portion and a second anode portion connected to each other, the first anode portion is exposed through the pixel opening, and the pixel defining layer covers the second anode portion; and
along a direction in which the first anode portion points to the second anode portion, a length L of the second anode portion satisfies that L≥1 mm.

19. A display device, comprising a display panel; wherein the display panel comprises a planarization layer, an anode on a side of the planarization layer, and a pixel defining layer on a side of the anode facing away from the planarization layer;
wherein the pixel defining layer is provided with a pixel opening, and part of the anode is exposed through the pixel opening; and
the planarization layer is provided with a groove, the groove surrounds the pixel opening, and the groove penetrates through at least part of the planarization layer; and the anode covers the groove, and an end of the anode is located at a side of the groove facing away from the pixel opening.

20. The display device of claim 19, further comprising an inorganic insulating layer on a side of the planarization layer facing away from the anode;
wherein the groove penetrates through the planarization layer, and the anode covering the groove is in contact with the inorganic insulating layer.
